(19) United States
(12) Patent Application Publication
(10) Pub. No.: US 2015/0020866 A1
(43) Pub. Date: Jan. 22, 2015

(54) PHOTOVOLTAIC MODULE WITH COOLING DEVICE

(71) Applicant: SAINT-GOBAIN GLASS FRANCE, Courbevoie (FR)

(72) Inventor: Hans-Werner Kuster, Aachen (DE)

(21) Appl. No.: 14/371,172

(22) PCT Filed: Mar. 7, 2013
(86) PCT No.: PCT/EP2013/054578

§ 371 Date: Jul. 8, 2014

(30) Foreign Application Priority Data
Mar. 30, 2012 (EP) 12162418.3

(51) Int. Cl. H01L 31/052; H01L 31/18

(52) U.S. Cl. CPC H01L 31/0521; H01L 31/18
USPC 136/246; 29/428

(57) ABSTRACT

A photovoltaic module with cooling device is described. The photovoltaic module has a laminated composite composed of a rear sheet, photovoltaic layer system, and front sheet arranged one above another, and a structural plate arranged on the rear side of the rear sheet. At least one channel running between a coolant inlet and a coolant outlet is introduced into the structural plate, at least two contact areas are formed on the surface of the structural plate, the contact areas being separated from one another by the channel and the structural plate being connected to the rear side via the contact areas, and the channel is at least partially filled with a liquid coolant.

The invention relates to a photovoltaic module with cooling device, a method for its production, and its use.

Photovoltaic modules can convert part of the sunlight striking them into electrical energy. It is known that the efficiency of this conversion depends decisively on the temperature of the photovoltaic modules. Optimal efficiencies are typically achieved in a temperature range from roughly 20° C. to roughly 50° C. However, as a result of direct sunlight and the sometimes significant heat losses during conversion of radiation energy into electrical energy, a photovoltaic module can be heated during operation to a temperature of as much as 100° C. This significantly reduces the efficiency of the generation of electrical energy.

An increase in the level of efficiency of a photovoltaic module can be achieved by cooling the photovoltaic module. Such cooling can, for example, be achieved by ventilating the rear side of the photovoltaic module. Significantly more effective cooling can be achieved by means of a liquid coolant.

A photovoltaic module that is mounted on a metal container filled with a liquid coolant is known from DE 197 47 325 A1. The cooling of the photovoltaic module is achieved by means of the release of heat to the coolant and the circulation of the coolant inside the metal container. The cooling effect is limited since no active cooling of the coolant is provided. In addition, such a solution has a large space requirement.

A photovoltaic module on the rear side of which a cooling device is arranged is known from US 2011/0168233 A1. The cooling device comprises a base plate and a cooling plate. A cooling pipe, through which a liquid coolant is pumped, is installed on the cooling plate. However, the production of the photovoltaic module is complex due to the many elements of the cooling device.

The object of the present invention is to provide a photovoltaic module with an improved cooling device that is simple and economical to produce, has a small space requirement, and enables effective cooling of the photovoltaic module.

The object of the present invention is accomplished according to the invention by means of a photovoltaic module with cooling device according to independent claim 1. Preferred embodiments emerge from the subclaims.

The photovoltaic module with cooling device according to the invention comprises at least the following characteristics:
a laminated composite composed of rear pane, photovoltaic layer system, and front pane arranged one above another, and
a structural plate arranged on the rear side of the rear pane,
   wherein
at least one channel running between a coolant inlet and a coolant outlet is introduced into the structural plate,
on the surface of the structural plate at least two contact surfaces are implemented that are separated from one another by the channel and by means of which the structural plate is connected to the rear side of the rear pane, and
the channel is at least partially filled with a liquid coolant.

In the context of the invention, “front pane designates the pane of the photovoltaic module facing the incidence of light. “Rear pane” designates the pane facing away from the incidence of light. The front pane and the rear pane have in each case a front side and a rear side. In the context of the invention, “front side” designates the side facing the incidence of light. “Rear side” designates the side facing away from the incidence of light. The rear side of the front pane and the front side of the rear pane face each other and are bonded to each other via an intermediate layer by lamination.

In the context of the invention, when an element “contains” at least one material, this includes the case that the element is made of the material.

The structural plate is, according to the invention, formed with at least one channel running between a coolant inlet and a coolant outlet. A depression is formed by the channel on a first surface of the structural plate and a corresponding elevation is formed on an opposing second surface of the structural plate. The first surface of the structural plate has at least two contact surfaces, which are arranged in a common flat plane. The two contact surfaces are separated from one another by the channel and flank the channel. The structural plate is connected via the contact surfaces to the rear side of the rear pane. A pipe for a liquid coolant is formed by the channel in the structural plate and the rear side of the rear pane. The channel runs between a coolant inlet and a coolant outlet, which constitute openings of the pipe. The channel can be connected via these openings to a coolant flow pipe and to a coolant return pipe. The coolant can thus be directed through the channel and release the heat absorbed outside the photovoltaic module by suitable means.

The channel is preferably formed by transformations in the structural plate and forms a depression on the surface of the structural plate facing the rear pane and an elevation on the surface of the structural plate facing away from the rear pane.

The structural plate provides an economical and effective cooling device that is simple to produce. In addition, the structural plate provides an interface for mounting the photovoltaic module at the site of use and effects a reinforcement or stiffening of the photovoltaic module. The installation of additional reinforcement elements is thus unnecessary if such reinforcement is desired, for example, in the case of a photovoltaic module with low thicknesses of the front pane and the rear pane. These are major advantages of the present invention.

The structural plate preferably has a thickness from 0.1 mm to 3.0 mm, particularly preferably from 0.3 mm to 0.8 mm. This is particularly advantageous with regard to simple introduction of the channels according to the invention into the structural plate, the stability, and the reinforcement action of the structural plates. The structural plate preferably has a constant thickness. In the context of the invention, “thickness of the structural plate” designates the material thickness.

The structural plate can, in principle, be made from any suitable metal or any suitable alloy. The structural plate preferably contains at least steel and/or aluminum. This is particularly advantageous with regard to economical production and the stability of the structural plate.

The channel according to the invention in the structural plate preferably has a depth from 0.5 mm to 20 mm, particularly preferably from 2 mm to 10 mm. This is particularly advantageous with regard to the cooling effect and low space requirement of the structural plate. The depth of the channel is determined in a cross-section perpendicular to the spread direction of the channel. In the context of the invention, the depth of the channel is the maximum perpendicular distance of the surface of the structural plate facing the rear pane in the region of the channel from the plane in which the contact surfaces are arranged. The depth of the channel is preferably constant along the spread direction of the channel.

The channel preferably has a width from 2 mm to 50 mm, particularly preferably from 5 mm to 20 mm. This is particularly advantageous with regard to the cooling effect and the stable connection between the structural plate and the rear pane. In the context of the invention, the “width of the channel” designates the width of the channel in the plane in which the contact surfaces are arranged.

According to the invention, the profile of the channel in the cross-section perpendicular to the spread direction of the channel is not restricted to a specific shape. The profile of the channel can, for example, have the shape of a rectangle, a triangle, a segment of a circle, a segment of an ellipse, or a trapezoid. Profiles that become narrower with increasing distance from the rear pane, for example, triangles, trapezoid, circle segments, or ellipse segments, can be preferable because, with the same amount of coolant, they yield a larger contact surface of the coolant to the rear pane than, for example, a rectangular profile.

The channel extends preferably meanderingly over the structural plate. Thus, a particularly advantageous cooling effect is achieved. The channel particularly preferably has sections parallel to each other that are connected to each other by winding sections. Adjacent parallel sections of the channel are preferably from 5 mm to 100 mm apart. Thus, particularly good results are achieved in terms of cooling.

The channel is preferably completely filled with the coolant. Thus, a particularly advantageous cooling effect is achieved.

The coolant inlet and the coolant outlet are preferably arranged on at least one side edge of the structural plate. This is particularly advantageous with regard to simple production of the structural plates according to the invention since the coolant inlet and a coolant outlet can be provided at the time of introduction of the channel without additional process steps such as drilling, for instance. The pipe for the cooling liquid then has two openings on at least one side edge of the structural plate that can be connected to a coolant flow pipe and a coolant return pipe. Such a side connection is clearly more space-saving at the site of use than a connection via the rear side of the structural plate since the photovoltaic module can be arranged at a shorter distance from the subsurface, for example, a building roof. The coolant inlet and the coolant outlet can be arranged on the same or on two different side edges of the structural plate.

In an advantageous embodiment of the invention, the coolant inlet and the coolant outlet are arranged on two opposite side edges of the structural plate. The connection of the channel to a coolant flow pipe and to a coolant return pipe is then particularly simple and space-saving since the coolant flow pipe and the coolant return pipe can be arranged on opposite sides of the photovoltaic module. In particular, a plurality of photovoltaic modules according to the invention can be connected simply in parallel with the same coolant flow pipe and the same coolant return pipe.

The channel is preferably introduced into the structural plate by transformations of a structural plate that is flat in the initial condition, for example, by deep-drawing or embossing.

The connection between the contact surfaces of the structural plate and of the rear pane is preferably accomplished using an adhesive. The adhesive must be suitable for providing a connection of the structural plate and the rear pane that is leakproof relative to the coolant and chemically as well as mechanically stable. Suitable adhesives are, for example, polyurethane adhesives.

The contact surfaces are preferably formed on the entire surface of the structural plate facing the rear pane minus the region of the channel and completely covered with the adhesive. Thus, advantageously, a particularly stable connection is achieved between the structural plate and the rear pane.

In an advantageous embodiment, one or a plurality of mounting elements are arranged on the surface of the structural plate facing away from the rear pane. By means of the mounting elements, the photovoltaic module can be mounted at the site of use, for example, on a rack. The mounting is accomplished, for example, by screwing, clamping, gluing the mounting elements, and/or by inserting the mounting elements into a rail. The mounting elements are preferably arranged in the edge region of the structural plate. The structural plate according to the invention advantageously provides, through the mounting elements, an interface for mounting the photovoltaic module at the site of use.

The mounting elements can, for example, have an angular cross-section, wherein a flat, subregion implemented parallel to the rear side of the rear pane projects beyond the side edges of the photovoltaic module. The mounting elements can be installed on the structural plate, for example, by welding, soldering, or gluing. Alternatively, the mounting elements can be formed in one piece with the structural plate, with side edges or projecting regions of the side edges of the structural plate that are flat in the initial condition being bent to form a mounting element.

In principle, any suitable cooling liquid with adequate thermal conductivity known to the person skilled in the art can be used as the coolant. The coolant can, for example, contain at least water or a water-glycol mixture. The coolant can also contain additives, oils, or gases.

The front pane preferably contains a non-prestressed, partially prestressed, or prestressed glass or a hardened glass, for example, a thermally or chemically hardened glass. The front pane preferably contains soda lime glass, low-iron soda lime glass, or borosilicate glass. This is particularly advantageous with regard to the stability of the photovoltaic module, the protection of the photovoltaic layer system against mechanical damage, and the transmission of sunlight through the front pane.

The rear pane contains, in an advantageous embodiment, a non-prestressed, partially prestressed, or prestressed glass or a hardened glass, for example, a thermally or chemically hardened glass. The rear pane preferably contains soda lime glass, low-iron soda lime glass, or borosilicate glass. The rear pane can, however, alternatively, contain a plastic, for example, polyethylene, polypropylene, polycarbonate, polymethyl methacrylate, and/or mixtures thereof, a glass fiber reinforced plastic, a metal, or a metal alloy, for example, stainless steel.

The front pane and the rear pane preferably have, in each case, a thickness from 0.1 mm to 10 mm, for example, from 1.5 mm to 5 mm.

In an advantageous embodiment of the invention, the front pane and/or the rear pane have very low thicknesses. The front pane and/or the rear pane preferably have a thickness from 1 mm to 6 mm, particularly preferably from 2 mm to 4 mm. Such photovoltaic modules have an advantageously low weight. The cooling device according to the invention is particularly advantageous for photovoltaic modules with low pane thicknesses since, by means of the structural plate according to the invention, a reinforcement and stiffening of the photovoltaic module is achieved such that no additional reinforcement elements need be installed.

The area of the front pane and of the rear pane can be from 100 cm² all the way to 18 m², preferably from 0.5 m² to 3 m². The front pane and the rear pane can be flat or bent.

The photovoltaic layer system effects the charge carrier separation necessary for the conversion of radiation energy into electrical energy. The photovoltaic layer system preferably comprises at least one photovoltaically active absorber layer between a front electrode layer and a rear electrode layer. The front electrode layer is arranged on the side of the absorber layer facing the incidence of light. The rear electrode layer is arranged on the side of the absorber layer facing away from the incidence of light.

The photovoltaically active absorber layer is not restricted according to the invention to a specific type. The absorber layer can contain, for example, monocrystalline, polycrystalline, micromorphous, or amorphous silicon, semiconducting organic polymers or oligomers, cadmium telluride (CdTe), gallium arsenide (GaAs), or cadmium selenide (CdSe).

In a preferred embodiment of the invention, the absorber layer contains a p-conductive chalcopyrite semiconductor such as a compound of the group copper indium sulfur/selenium (CIS), for example, copper indium diselenide (CuInSe₂), or a compound of the group copper indium gallium sulfur/selenium (CIGS), for example, Cu(InGa)(SSe)₂. Photovoltaic modules with CI(G)S-based absorber layers have a particularly high temperature coefficient, i.e., a particularly strong reduction of the efficiency level with an increasing temperature. The temperature coefficient relative to the power output is roughly in the range from −0.35%/° C. to −0.5%/° C. The temperature dependency of the efficiency level is thus clearly more pronounced than, for example, with photovoltaic modules with an absorber layer based on amorphous silica (roughly from −0.18%/° C. to −0.23%/° C.) or cadmium telluride (roughly from −0.18%/° C. to −0.25%/° C.). Consequently, with such photovoltaic modules, particularly good results are achieved by means of the cooling device according to the invention.

In an alternative preferred embodiment of the invention, the absorber layer contains polycrystalline silicon. A photovoltaic module with such an absorber layer also has a high temperature coefficient, roughly in the range from −0.32%/° C. to −0.51%/° C. The level of efficiency can be particularly advantageously increased by means of the cooling device according to the invention.

Photovoltaic modules based on monocrystalline silicon also have a high temperature coefficient, roughly in the range from −0.32%/° C. to −0.51%/° C. The level of efficiency can be particularly advantageously increased by means of the cooling device according to the invention.

The values reported for the temperature coefficients are taken from the following publication: Volker Quaschning, Regenerative Energiesysteme [Regenerative Energy Systems], Carl Hanser Verlag 2009, p. 190 (ISBN 978-3446421516).

The absorber layer preferably has a layer thickness from 500 nm to 5 μm, particularly preferably from 1 μm to 3 μm. The absorber layer can be doped with metals, preferably sodium.

The photovoltaic layer system can be installed on the front side of the rear pane (substrate configuration). The photovoltaic layer system can, alternatively, be installed on the rear side of the front pane (superstrate configuration). The substrate configuration and the superstrate configuration are particularly common with thin-film photovoltaic modules.

However, alternatively, the photovoltaic layer system can be arranged between a first and a second film of the intermediate layer, as is particularly common with photovoltaic modules with a crystalline absorber layer. In the context of the invention, the photovoltaic layer system is then arranged in the intermediate layer.

In a preferred embodiment, the photovoltaic module according to the invention has the substrate configuration. Here, particularly effective cooling of the photovoltaic structure is achieved through the structural plates on the rear side of the rear pane according to the invention.

The rear electrode layer can, for example, contain at least one metal, preferably molybdenum, titanium, tungsten, nickel, titanium, chromium, and/or tantalum. The rear electrode layer preferably has a layer thickness from 300 nm to 600 nm. The rear electrode layer can comprise a layer stack of different individual layers. Preferably, the layer stack includes a diffusion barrier layer made, for example, of silicon nitride, to prevent diffusion of, for example, sodium out of the substrate into the photovoltaically active absorber layer.

The front electrode layer is transparent in the spectral range in which the absorber layer is sensitive. The front electrode layer can, for example, contain an n-conductive semiconductor, preferably aluminum-doped zinc oxide or indium tin oxide. The front electrode layer preferably has a layer thickness from 500 nm to 2 μm.

The electrode layers can also contain silver, gold, copper, nickel, chromium, tungsten, tin oxide, silicon dioxide, silicon nitride, and/or combinations as well as mixtures thereof.

The photovoltaic layer system preferably has a peripheral distance from the outer edges of the photovoltaic module from 5 mm to 20 mm, particularly preferably from 10 mm to 15 mm, in order to be protected on the edge against the entry of moisture or shadowing by mounting elements.

The rear side of the front pane is bonded by at least one intermediate layer to the front side of the rear pane. The bonding between the front pane and the rear pane takes place over a large area via the photovoltaic layer system. The intermediate layer preferably contains thermoplastic plastics, such as polyvinyl butyral (PVB) and/or ethylene vinyl acetate (EVA) or a plurality of layers thereof, preferably with thicknesses from 0.3 mm to 0.9 mm. The intermediate layer can also contain polyurethane (PU), polypropylene (PP), polyacrylate, polyethylene (PE), polycarbonate (PC), polymethyl methacrylate, polyvinyl chloride, polyacetate resin, casting resins, acrylates, fluorinated ethylene propylenes, polyvinyl fluoride, ethylene tetrafluoroethylene, copolymers and/or mixtures thereof.

The front electrode layer and the rear electrode layer are electrically contacted by elements known per se, for example, by busbars and foil conductors. The foil conductors can, for example, be guided out of the photovoltaic module on the side in the region of the intermediate layer or through at least one hole in the rear pane in the region of the contact surfaces of the structural plate.

The front pane and/or the rear pane can have coatings known per se, for example, antireflective layers, anti-adhesive layers, anti-scratch layers, and/or diffusion barrier layers. The photovoltaic module can include other elements known per se, such as mounting means, frames, and/or fittings.

The photovoltaic module according to the invention is preferably operated inside an arrangement. The arrangement according to the invention for cooling a photovoltaic module comprises at least the following characteristics:
at least one photovoltaic module according to the invention,
a coolant flow pipe, which is connected to the coolant inlet of the structural plate of the photovoltaic module,
a coolant return pipe, which is connected to the coolant outlet of the structural plate of the photovoltaic module,
a coolant cooler with at least one coolant inlet and at least one coolant outlet, wherein the coolant inlet of the coolant cooler is connected to the coolant return pipe and the coolant outlet of the coolant cooler is connected to the coolant flow pipe, and
a liquid coolant in the channel of the structural plate, the coolant flow pipe, the coolant return pipe, and the coolant cooler.

The pipe formed by the channel in the structural plate and the rear side of the rear pane, the coolant flow pipe, the coolant cooler, and the coolant return pipe form a closed coolant circuit. The coolant heated in the region of the photovoltaic module is fed via the coolant return pipe to the coolant cooler, where the coolant releases heat and is cooled to a lower temperature. The cooled coolant is reintroduced via the coolant flow pipe into the channel of the structural plate. By means of the coolant cooler, a particularly effective cooling effect for the photovoltaic module is achieved.

The coolant flow pipe and the coolant return pipe can be implemented, for example, as pipes and/or hose lines. The connection between the channel of the structural plate and the coolant flow pipe or the coolant return pipe, respectively, can be achieved, for example, by a connection piece such as a connection pipe, that is sealingly glued, screwed, welded, or soldered to the structural plate. For the sealing of the connection between the channel and the coolant flow pipe or the coolant return pipe, respectively, suitable sealing means can also be used.

In an advantageous embodiment, the arrangement for cooling a photovoltaic module further includes a pump that is suitable for pumping the coolant through the closed coolant circuit.

The circulation of the coolant in the coolant circuit is actively achieved by means of the pump, which results in a particularly advantageous cooling effect. However, alternatively, the circulation of the coolant can also be achieved with suitable positioning of the coolant flow pipe, the coolant return pipe, the coolant cooler, and the photovoltaic module by means of the convection caused by the heated coolant.

In an advantageous embodiment, the coolant cooler is implemented as air cooling. This is particularly advantageous with regard to simple, space-saving, and economical production of the arrangement and low maintenance intensity of the arrangement. In this case, the coolant cooler preferably comprises at least one pipe that runs between the coolant flow pipe and the coolant return pipe. The pipe preferably has high thermal conductivity and contains, for example, at least copper, aluminum, steel, or other suitable materials. The pipe can run in a straight line or, for example, windingly or meanderingly from the coolant return pipe to the coolant flow pipe. Even a plurality of pipes can be connected in parallel to the coolant flow pipe and the coolant return pipe.

The coolant cooler can, however, even be realized by a heat exchanger with a secondary coolant circuit.

In an advantageous embodiment, a plurality of photovoltaic modules, for example, from 2 to 40 photovoltaic modules, are connected to the coolant flow pipe and the coolant return pipe. The cooling of the plurality of photovoltaic modules is advantageously achieved by the same coolant circuit. Particularly advantageous cooling is achieved when the plurality of photovoltaic modules are connected in parallel to the coolant flow pipe and the coolant return pipe. However, the plurality of photovoltaic modules can, in principle, also be connected in series to the coolant flow pipe and the coolant return pipe.

The coolant circuit can include other elements deemed suitable by the person skilled in the art, such as stopcocks, valves, for example, an air release valve, or closable openings for the filling and changing of the coolant.

The object of the invention is further accomplished by a method for producing a photovoltaic module according to the invention, wherein at least

(a) at least one channel running between the coolant inlet and the coolant outlet is introduced into the structural plate,

(b) the structural plate is connected to the rear side of the rear pane via at least two contact surfaces, which are separated from one another by the channel, and

(c) the channel is at least partially filled with a liquid coolant.

The channel is preferably formed by transformations in a structural plate that is flat in the initial condition, for example, by deep-drawing or embossing.

To prepare the laminated composite composed of the rear pane, the photovoltaic layer system, and the front pane arranged one over another, the photovoltaic layer system is installed on the front side of the rear pane or on the rear side of the front pane or placed in the intermediate layer. Then, the front side of the rear pane is bonded to the rear side of the front pane via the intermediate layer under the action of heat, vacuum, and/or pressure, for example, by autoclaving methods, vacuum bag methods, vacuum ring methods, calendering methods, vacuum laminators, or by combinations thereof.

If the photovoltaic module is a thin-film photovoltaic module, the individual layers of the photovoltaic layer system are preferably applied by cathode sputtering, evaporation, or chemical gas phase deposition (chemical vapour deposition, CVD). The placing of the photovoltaic layer system in the intermediate layer includes the arranging of the photovoltaic layer system between a first and second layer of the intermediate layer.

The preparation of the laminated composite composed of the rear pane, the photovoltaic layer system, and the front pane arranged one above another and the introduction of the channel into the structural plate can take place in any temporal sequence. The bonding of the structural plate to the rear pane takes place after the preparation of the laminated composite composed of the rear pane, the photovoltaic layer system, and the front pane arranged one above another.

The bonding of the structural plate and the rear pane is preferably achieved by gluing.

Preferably, the back electrode layer and/or the front electrode layer are electrically conductively connected for electrical contacting after the installation of the photovoltaic layer system and before the bonding of the front pane and the rear pane with, for example, a foil conductor. The electrically conductive connection is achieved, for example, by welding, bonding, soldering, clamping, or gluing with an electrically conductive adhesive. The connection of the foil conductor to the rear electrode layer and/or the front electrode layer can also be achieved via a busbar.

The method can include other steps known per se, for example, the division of the photovoltaic layer systems into the individual photovoltaically active regions (so-called solar cells) by the incisions in individual layers or individual groups of layers of the layer system or the creation of a coating-free edge region.

In a preferred embodiment, temporally, between process steps (b) and (c), a coolant flow pipe and the coolant inlet of the structural plate, and a coolant return pipe are connected to the coolant outlet of the structural plate. In addition, the coolant flow pipe is connected to a coolant outlet of a coolant cooler and the coolant return pipe is connected to a coolant inlet of the coolant cooler. The channel, the coolant flow pipe, the coolant return pipe, and the coolant cooler are then at least partially filled with a liquid coolant, for example, via closable openings.

Another aspect of the invention comprises the use of a photovoltaic module with cooling device according to the invention on a roof of a building or a motor vehicle for transportation on water, on land, or in the air, on a building façade or in open areas.

The invention also comprises the use of a structural plate according to the invention on the rear side of the rear pane of a photovoltaic module to cool the photovoltaic layer system, preferably to a temperature from 20° C. to 50° C.

The invention is explained in detail with reference to drawings and exemplary embodiments. The drawings are a schematic representation and not true to scale. The drawings in no way restrict the invention. They depict:

FIG. 1 a top plan view of the side facing away from the incidence of light of a photovoltaic module with cooling device according to the invention,

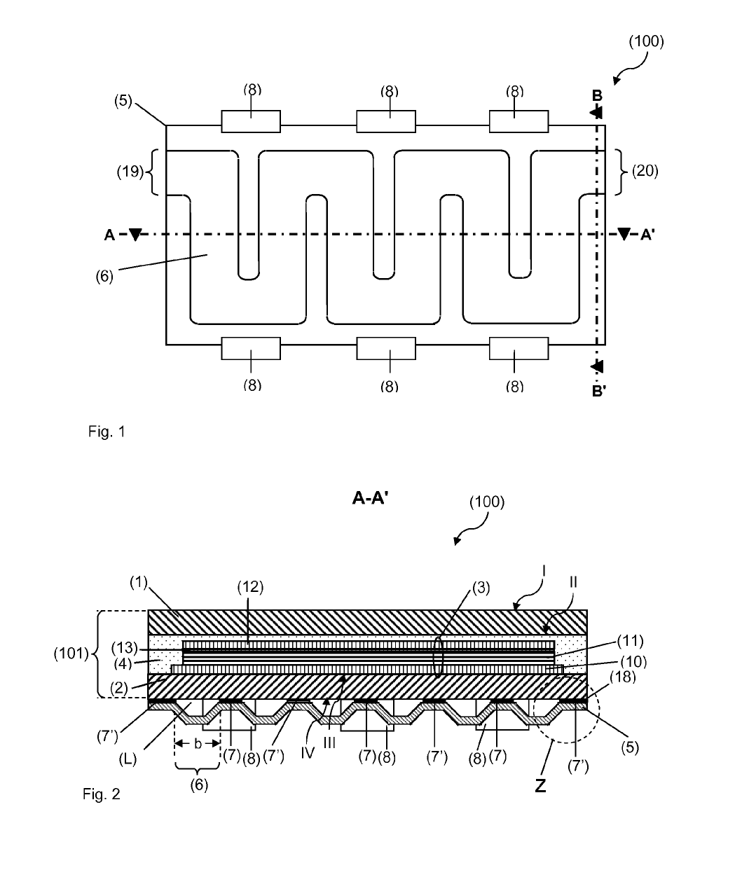

FIG. 2 a section along A-A′ through the photovoltaic module according to FIG. 1,

FIG. 2a an enlarged view of the section Z of FIG. 2,

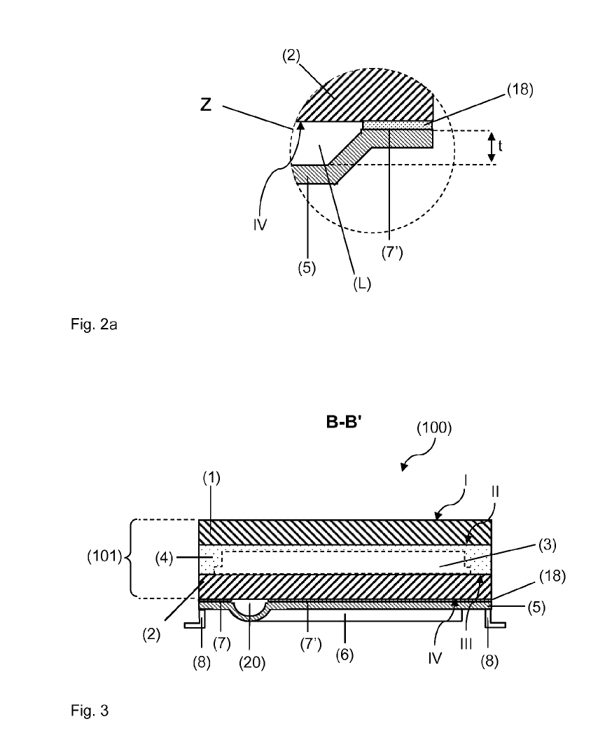

FIG. 3 a section along B-B′ through the photovoltaic module according to FIG. 1,

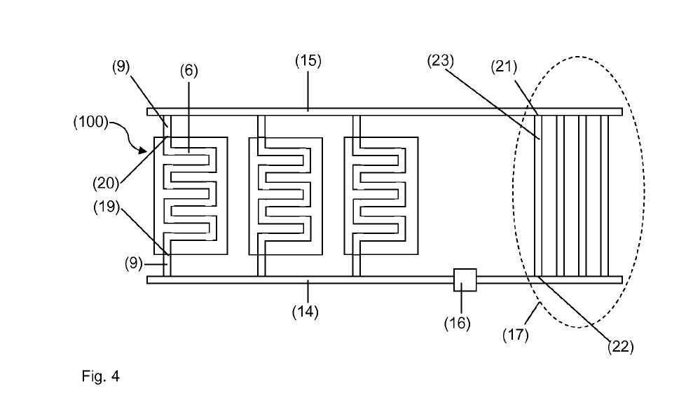

FIG. 4 a schematic representation of an arrangement according to the invention for cooling a photovoltaic module, and

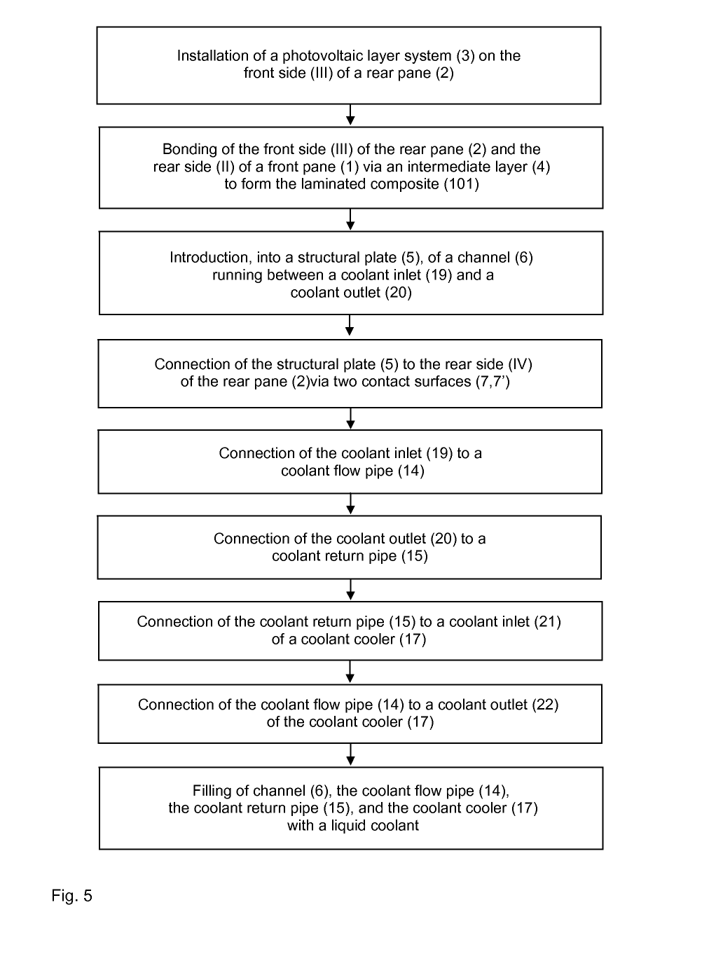

FIG. 5 an exemplary embodiment of the method according to the invention with reference to a flowchart.

FIG. 1, FIG. 2, FIG. 2a and FIG. 3 depict, in each case, a detail of a photovoltaic module 100 with cooling device according to the invention. The photovoltaic module 100 comprises a front pane 1 with a front side (I) and a rear side (II) and a rear pane 2 with a front side (III) and a rear side (IV). The front side (I) of the front pane 1 faces the incidence of light. A photovoltaic layer system 3 is installed on the front side (III) of the rear pane 2. The rear side (II) and the front side (III) are extensively bonded to one another via the photovoltaic layer system 3 by means of an intermediate layer 4. The front pane 1, the rear pane 2, the photovoltaic layer system 3, and the intermediate layer 4 form a laminated composite 101. The front pane 1 is transparent to sunlight and is made of hardened, extra white glass with a low iron content. The rear pane 2 is made of soda lime glass. The front pane 1 and the rear pane 2 have a thickness of 2.85 mm. The photovoltaic module 100 has a size of 1.6 m×0.7 m. The intermediate layer 4 contains polyvinyl butyral (PVB) and has a layer thickness of 0.76 mm.

The photovoltaic module 100 is a CIS thin-film photovoltaic module in the substrate configuration. The photovoltaic layer system 3 comprises a rear electrode layer 10 arranged on the front side (III) of the rear pane 2, which contains molybdenum and has a layer thickness of roughly 300 nm. The photovoltaic layer system 3 further contains a photovoltaically active absorber layer 11, which contains sodium-doped Cu(InGa)(SSe)₂ and has a layer thickness of roughly 2 μm. The photovoltaic layer system 3 further contains a front electrode layer 12, which contains aluminum-doped zinc oxide (AZO) and has a layer thickness of roughly 1 μm. A buffer layer 13 that contains a single layer of cadmium sulfide (CdS) and a single layer of intrinsic zinc oxide (i-ZnO) is arranged between the front electrode layer 12 and the absorber layer 11. The buffer layer effects an electronic adaptation between the absorber layer 11 and the front electrode layer 12. The photovoltaic layer system 3 is divided, using a method known per se for producing a thin-film photovoltaic module, into individual photovoltaic active regions, so-called “solar cells”, that are connected in series to each other via a region of the rear electrode layer 10. The photovoltaic layer system 3 is mechanically abrasively decoated in the edge region of the rear pane 2 with a width of 15 mm. The front electrode layer 12 and the rear electrode layer 10 are electrically contacted via foil conductors (not shown) in a method known per se.

A structural plate 5 is arranged on the rear side (IV) of the rear pane 2. The structural plate 5 is made of steel and has a thickness of 0.8 mm. A channel 6 is introduced into the structural plate 5 by deep drawing. On two opposite side edges of the structural plate 5, a coolant inlet 19 and a coolant outlet 20 are formed by the channel 6. The channel 6 runs meanderingly between the coolant inlet 19 and the coolant outlet 20. The channel 6 has straight sections arranged parallel to each other, with adjacent straight sections connected to one another by winding sections. The width b of the channel 6 is depicted very much enlarged for better visualization. In an actual embodiment, the channel 6 has, for example, a width b of 20 mm and, accordingly, a significantly larger number of meandering turns. Adjacent straight sections of the channel 6 are spaced, for example, 20 mm apart.

On the surface of the structural plate 5 facing the rear pane 2, two contact surfaces 7, 7′ that are separated from one another by the channel 6 are formed. The contact surfaces 7, 7′ are arranged in a flat plane. The structural plate 5 is bonded via the contact surfaces 7, 7′ to the rear side (IV) of the rear pane 2 by means of an adhesive 18. A coolant pipe (L) that is filled with a liquid coolant (not shown) is formed by the channel 6 and the rear side (IV). By means of the adhesive 18, which is a polyurethane adhesive, a durably stable connection that is leakproof relative to the coolant is provided between the structural plate 5 and the rear pane 2. The coolant inlet 19 and the coolant outlet 20 provide openings of the pipe (L), which are provided for the connection of a coolant flow pipe and a coolant return pipe within a cooling circuit.

The channel 6 has, in the cross-section perpendicular to its spread direction, the shape of a trapezoid. Only in the area of the side edges is the cross-section implemented rounded. In order to be more simply connected to the coolant flow pipe or return pipe. The channel 6 has a depth t of 5 mm.

In the edge region of the surface of the structural plate 5 facing away from the rear pane 2, mounting elements 8 are welded on. The mounting elements 8 are made of steel and have an angular profile, with a region of each mounting element 8 projecting beyond the side edges of the photovoltaic module 100. The photovoltaic module 100 can be mounted on a rack via the projecting regions of the mounting elements 8, for example, by screwing or insertion into a carrier rail.

By means of the structural plate 5 according to the invention, a space-saving pipe (L) that is simple and economical to produce is provided for a liquid coolant. By means of the cooling of the photovoltaic module 100, the temperature of the photovoltaic layer system 3 can be maintained in a range from roughly 20° C. to 50° C. during operation. Thus, the level of efficiency of the conversion of radiation energy into electrical energy is significantly increased. Such cooling is particularly advantageous with CIS thin-film photovoltaic modules because of their high temperature coefficient. The side openings of the pipe formed by the structural plate 5 permit the connection of a coolant flow pipe and a coolant return pipe in the region of the side edges of the photovoltaic module 100. Such a side connection is significantly more space-saving at the site of use than a connection via the rear side of the structural plate 5, since the photovoltaic 100 can be arranged at a shorter distance from the subsurface, for example, a building roof. The structural plate 5 also results in a reinforcement and stiffening of the photovoltaic module 100, which is advantageous due to the low thickness of the front pane 1 and of the rear pane 2. Additional reinforcement elements are unnecessary. Moreover, through the mounting elements 8, the structural plate 5 constitutes the interface for the mounting of the photovoltaic module 100 at the site of use. These are major advantages of the present invention.

FIG. 4 depicts a schematic view of an arrangement according to the invention for cooling a photovoltaic module. The arrangement comprises, by way of example, three photovoltaic modules 100 according to the invention. The channel 6 of the structural plate 5 of each photovoltaic module 100 is connected via the coolant inlet 19 to a coolant flow pipe 14. The channel 6 of the structural plate 5 of each photovoltaic module 100 is connected via the coolant outlet 20 to a coolant return pipe 15. The photovoltaic modules 100 are connected in parallel to the coolant flow pipe 14 and the coolant return pipe 15 such that the coolant flows between coolant flow pipe 14 and coolant return pipe 15 in each case through only one photovoltaic module 100. The coolant flow pipe 14 and the coolant return pipe 15 are implemented as pipes made of steel. The connection between the channel 6 and the coolant inlet 19 or the coolant outlet 20, respectively, is accomplished in each case via a connection piece 9. Each connection piece 9 comprises two short metal pipes and a hose arranged between the metal pipes and clamped onto the metal pipes. One metal pipe is welded to the structural plate 5 in the region of the coolant inlet 19 (or to the coolant outlet 20, respectively); the other metal pipe is connected to the coolant flow pipe 14 (or to the coolant return pipe 15, respectively), for example, screwed on with threads. The arrangement further comprises a pump 16 that is arranged between two sections of the coolant flow pipe 14.

The coolant flow pipe 14 and the coolant return pipe 15 are connected to each other away from the photovoltaic module 100 via a coolant cooler 17. The coolant cooler 17 is an air cooler and comprises four pipes 23 made of steel, which run in parallel between the coolant flow pipe 14 and the coolant return pipe 15. Each pipe 23 of the coolant cooler 17 has a coolant inlet 21 and a coolant outlet 22, with the coolant inlet 21 connected to the coolant return pipe 15 and the coolant outlet 22 connected to the coolant flow pipe 14, for example, screwed on with threads.

A closed coolant circuit is provided by the pipes (L) formed by the channels 6 of the structural plates 5 and the rear panes 2, the coolant flow pipe 14 with the pump 16, the coolant return pipe 15, the connection pieces 9, and the coolant cooler 17. The coolant circuit is filled, for example, with water as coolant. The coolant is pumped by the pump 16 through the coolant circuit. In the region of the photovoltaic module 100, the coolant absorbs heat from the photovoltaic modules 100 and thus yields a reduction in the temperature of the photovoltaic layer system 3. The heated coolant releases the heat into the surrounding air through the coolant cooler 17. The temperature of the photovoltaic layer system 3 can thus be durably maintained in a range from 20° C. to 50° C.

FIG. 5 depicts, by way of example, the method according to the invention for producing a photovoltaic module with cooling device.

It was unexpected and surprising for the person skilled in the art that effective cooling of the photovoltaic layer system of a photovoltaic module can be achieved simply, space-savingly, and economically by means of the structural plate according to the invention. It was further unexpected and surprising for the person skilled in the art that, at the same time, by means of the structural plate according to the invention, a reinforcement and stiffening of the photovoltaic module and an interface for mounting the photovoltaic module can be provided.

List of Reference Characters:
(1) front pane
(2) rear pane
(3) photovoltaic layer system
(4) intermediate layer
(5) structural plate
(6) channel
(7) contact surface of the structural plate 5
(7′) contact surface of the structural plate 5
(8) mounting element
(9) connection piece
(10) rear electrode layer
(11) absorber layer
(12) front electrode layer
(13) buffer layer
(14) coolant flow pipe
(15) coolant return pipe
(16) pump
(17) coolant cooler
(18) adhesive
(19) coolant inlet of the structural plate 5
(20) coolant outlet of the structural plate 5
(21) coolant inlet of the coolant cooler 17
(22) coolant outlet of the coolant cooler 17
(23) pipe
(100) photovoltaic module
(101) laminated composite composed of front pane 1, photovoltaic layer system 3, and rear pane 2
(L) coolant pipe
b width of the channel 6
t depth of the channel 6
I front side of the front pane 1
II rear side of the front pane 1
III front side of the rear pane 2
IV rear side of the rear pane 2
A-A′ section line
B-B′ section line
Z section of the photovoltaic module 100

1. A photovoltaic module with cooling device, comprising at least:
a laminated composite composed of a rear pane, a photovoltaic layer system, and a front pane arranged one above another, and
a structural plate arranged on the rear side of the rear pane, wherein
at least one channel running between a coolant inlet and a coolant outlet is introduced into the structural plate,
at least two contact surfaces are formed on the surface of the structural plate, which contact surfaces are separated from one another by the channel, and via which contact surfaces the structural plate is connected to the rear side, and
the channel is at least partially filled with a liquid coolant.

2. The photovoltaic module according to claim 1, wherein the channel is formed by transformations in the structural plate and forms a depression on the surface of the structural plate facing the rear pane and an elevation on the surface of the structural plate facing away from the rear pane.

3. The photovoltaic module according to claim 1, wherein a coolant line is formed by the channel and the rear side.

4. The photovoltaic module according to claim 1, wherein the coolant inlet and the coolant outlet are arranged on at least one side edge of the structural plate, preferably on two opposite side edges, and wherein the channel preferably runs meanderingly.

5. The photovoltaic module according to claim 1, wherein the structural plate contains at least steel and/or aluminum.

6. The photovoltaic module according to claim 1, wherein the structural plate has a thickness from 0.1 mm to 3.0 mm, preferably from 0.3 mm to 0.8 mm, and wherein the thickness of the structural plate is preferably constant.

7. The photovoltaic module according to claim 1, wherein the channel has a depth from 0.5 mm to 20 mm, preferably from 2 mm to 10 mm, and preferably has a width from 2 mm to 50 mm, particularly preferably from 5 mm to 20 mm.

8. The photovoltaic module according to claim 1, wherein the structural plate is bonded to the rear pane by an adhesive, preferably a polyurethane adhesive.

9. The photovoltaic module according to claim 1, wherein at least one mounting element is arranged on the surface of the structural plate facing away from the rear pane.

10. The photovoltaic module according to claim 1, wherein the photovoltaic layer system has at least one photovoltaically active absorber layer between a front electrode layer and a rear electrode layer and wherein the photovoltaically active absorber layer contains at least polycrystalline silicon or copper indium (gallium)-sulfur/selen (CI(G)S) and wherein the photovoltaic layer system is preferably arranged on the front side of the rear pane.

11. An arrangement for cooling a photovoltaic module, comprising at least:
at least one photovoltaic module according to claim 1,
a coolant flow pipe, which is connected to the coolant inlet,
a coolant return pipe, which is connected to the coolant outlet,
a coolant cooler with at least one coolant inlet and at least one coolant outlet, wherein the coolant inlet is connected to the coolant return pipe and the coolant outlet is connected to the coolant flow pipe, and
a liquid coolant in the channel, the coolant flow pipe, the coolant return pipe, and the coolant cooler.

12. The arrangement according to claim 11, further comprising a pump that is suitable for pumping the coolant through the channel, the coolant flow pipe, the coolant return pipe, and the coolant cooler.

13. The arrangement according to claim 11, wherein the coolant cooler comprises at least one pipe running between the coolant flow pipe and the coolant return pipe.

14. A method for producing the photovoltaic module according to claim 1, comprising:
introducing at least one channel running between the coolant inlet and the coolant outlet into the structural plate,
connecting the structural plate to the rear side of the rear pane via the contact surfaces, and
at least partially filling the channel with a liquid coolant.

15. The method according to claim 14, wherein between process step (b) and process step (c), the method further comprises:
connecting a coolant flow pipe to the coolant inlet,
connecting a coolant return pipe to the coolant outlet,
connecting the coolant flow pipe to a coolant outlet of a coolant cooler, and
connecting the coolant return pipe to a coolant inlet of the coolant cooler, and
wherein in process step (c), the channel, the coolant flow pipe, the coolant return pipe, and the coolant cooler are at least partially filled with the liquid coolant.

16. A method comprising:
using the structural plate on the rear side of the rear pane of a photovoltaic module according to claim 1 for cooling the photovoltaic layer system to a temperature from 20° C. to 50° C.
